(19) United States
(12) Patent Application Publication
(10) Pub. No.: US 2024/0178243 A1
(43) Pub. Date: May 30, 2024

(54) SOLID-STATE IMAGING ELEMENT

(71) Applicant: Sharp Semiconductor Innovation Corporation, Tenri City (JP)

(72) Inventors: YUTA MOCHIZUKI, Tenri City (JP); Yoshinao Morikawa, Tenri City (JP); Takefumi Konishi, Tenri City (JP); Takeo Ushinaga, Tenri City (JP); Takeru Sakamoto, Tenri City (JP)

(21) Appl. No.: 18/512,947

(22) Filed: Nov. 17, 2023

(30) Foreign Application Priority Data
Nov. 30, 2022 (JP) 2022-192368

(51) Int. Cl. H01L 27/146

(52) U.S. Cl. CPC H01L 27/14612; H01L 27/14634; H01L 27/14636

(57) ABSTRACT

A solid-state imaging element includes: a plurality of first pixel output lines connected respectively to the plurality of first pixels; and a plurality of second pixel output lines connected respectively to the plurality of second pixels, wherein the plurality of first pixel output lines include a first closest pixel output line located closest to the plurality of second pixel output lines, the plurality of second pixel output lines include a second closest pixel output line located closest to the plurality of first pixel output lines, the first closest pixel output line is connected to a first pixel included in the plurality of first pixels, and the second closest pixel output line is connected to a second pixel included in the plurality of second pixels and disposed in the same pixel row as a pixel row that includes the first pixel.

### FIELD OF THE INVENTION

The present disclosure relates to solid-state imaging elements. The present application claims the benefit of priority to Japanese Patent Application, Tokugan, No. 2022-192368 filed on Nov. 30, 2022, the entire contents of which are incorporated herein by reference.

### BACKGROUND OF THE INVENTION

Japanese Unexamined Patent Application Publication, Tokukai, No. 2015-185823 discloses a solid-state imaging element.

The solid-state imaging element includes a plurality of pixel output lines for each column of pixels. In addition, each row of pixels is connected to one of the plurality of pixel output lines. In addition, pixel signals are outputted through the pixel output lines. Hence, the solid-state imaging element reads out the pixel signals at increased rates.

In addition, the solid-state imaging element exhibits reduced parasitic capacitances between the pixel output lines by, for example, dividing a wiring layer containing the plurality of pixel output lines and disposing shield-use wiring lines in the wiring layer containing the pixel output lines.

Hence, the solid-state imaging element prevents reduced image quality, such as appearance of horizontal lines, that could be caused by excessively small intervals between the pixel output lines (paragraphs 0032, 0072, and 0087).

### SUMMARY OF THE INVENTION

In the solid-state imaging element disclosed in Japanese Unexamined Patent Application Publication, Tokukai, No. 2015-185823, connection to the plurality of pixel output lines for a plurality of rows of pixels is similarly performed across all pixel columns. Therefore, if the number of the plurality of pixel output lines for each column of pixels is increased, the pixel signals outputted through the most adjacent pixel output lines come from pixels that are located far from each other. For example, suppose that a first column and a second column are adjacent to each other, that there are provided a plurality of first pixel output lines for the first column, and that there are provided a plurality of second pixel output lines for the second column. In this situation, the pixel signals outputted through a first pixel output line that is one of the plurality of first pixel output lines and that is the most adjacent to the plurality of second pixel output lines and a second pixel output line that is one of the plurality of second pixel output lines and that is the most adjacent to the plurality of first pixel output lines come from pixels that are located far from each other in the row direction. Therefore, the solid-state imaging element could exhibit reduced image quality caused by capacitance coupling and crosstalk between the most adjacent pixel output lines.

The present disclosure has been made in view of these problems. The present disclosure, in an aspect thereof, has an object to, for example, provide a solid-state imaging element capable of restraining reduced image quality that could be caused by crosstalk between the closest pixel output lines.

The present disclosure, in an aspect thereof, is directed to a solid-state imaging element including: a plurality of pixels arranged in a matrix and including: a first pixel column including a plurality of first pixels; and a second pixel column including a plurality of second pixels, the second pixel column being located adjacent to the first pixel column; a plurality of first pixel output lines connected respectively to the plurality of first pixels and arranged in a row direction; and a plurality of second pixel output lines connected respectively to the plurality of second pixels and arranged in the row direction, wherein the plurality of first pixel output lines include a first closest pixel output line located closest to the plurality of second pixel output lines, the plurality of second pixel output lines include a second closest pixel output line located closest to the plurality of first pixel output lines, the first closest pixel output line is connected to a first pixel included in the plurality of first pixels, and the second closest pixel output line is connected to a second pixel included in the plurality of second pixels and disposed in a same pixel row as a pixel row that includes the first pixel.

### BRIEF DESCRIPTION OF DRAWINGS

FIG. 1 is a schematic plan view of a solid-state imaging element in accordance with Embodiment 1.

FIG. 2 is a schematic plan view of a layout of pixels in a first pixel column and a second pixel column in the solid-state imaging element in accordance with Embodiment 1.

FIG. 3 is a schematic plan view of a solid-state imaging element in accordance with Reference Example 1.

FIG. 4 is a schematic plan view of a layout of pixels in a first pixel column and a second pixel column in the solid-state imaging element in accordance with Reference Example 1.

FIG. 5 is a schematic cross-sectional view of a plurality of pixel output lines and a plurality of wiring lines other than the plurality of pixel output lines in the solid-state imaging element in accordance with Embodiment 1.

FIG. 6 is a schematic cross-sectional view of a plurality of pixel output lines and a plurality of shield lines in a solid-state imaging element in accordance with Reference Example 2.

FIG. 7 is a timing chart illustrating temporal changes in the ON/OFF state of a reset transistor, the ON/OFF state of a transfer transistor, and the voltage output from a pixel output line when there is provided a shield line on each side of a pixel output line and when on each side of a pixel output line, there is provided another pixel output line that outputs the same signal as does the pixel output line.

FIG. 8 is a schematic plan view of a plurality of first wiring lines, a plurality of second wiring lines, a plurality of first vias, a plurality of second vias, a plurality of third vias, and a plurality of fourth vias in the solid-state imaging element in accordance with Embodiment 1.

FIG. 9 is a schematic plan view of a plurality of first wiring lines, a plurality of second wiring lines, a plurality of first vias, a plurality of second vias, a plurality of third vias, and a plurality of fourth vias in a solid-state imaging element in accordance with Reference Example 3.

FIG. 10 is a schematic plan view of a plurality of first pixel output lines and a plurality of second pixel output lines in the solid-state imaging element in accordance with Embodiment 1.

FIG. 11 is a schematic cross-sectional view of a semiconductor substrate, a plurality of first pixel output lines, a plurality of second pixel output lines, and a plurality of third pixel output lines in the solid-state imaging element in accordance with Embodiment 1 when the solid-state imaging element in accordance with Embodiment 1 is a front-side illumination type.

FIG. 12 is a schematic cross-sectional view of a semiconductor substrate, a plurality of first pixel output lines, a plurality of second pixel output lines, and a plurality of third pixel output lines in the solid-state imaging element in accordance with Embodiment 1 when the solid-state imaging element in accordance with Embodiment 1 is of a backside illumination type.

FIG. 13 is a schematic plan view of a plurality of first pixels, a plurality of first pixel output lines, a first circuit, and a second circuit in the solid-state imaging element in accordance with Embodiment 1.

FIG. 14 is a schematic plan view of a solid-state imaging element in accordance with Embodiment 2.

FIG. 15 is a schematic plan view of a layout of pixels in a first pixel column and a second pixel column in the solid-state imaging element in accordance with Embodiment 2.

FIG. 16 is a schematic plan view of a solid-state imaging element in accordance with Reference Example 4.

FIG. 17 is a schematic plan view of a layout of pixels in a first pixel column and a second pixel column in the solid-state imaging element in accordance with Reference Example 4.

FIG. 18 is a schematic cross-sectional view of a plurality of pixel output lines in a solid-state imaging element in accordance with Embodiment 3.

### DESCRIPTION OF EMBODIMENTS

The following will be describe embodiments of the present disclosure with reference to drawings. Note that identical and equivalent elements in the drawings are denoted by the same reference numerals, and description thereof is not repeated.

### 1 Embodiment 1

### 1.1 Solid-State Imaging Element

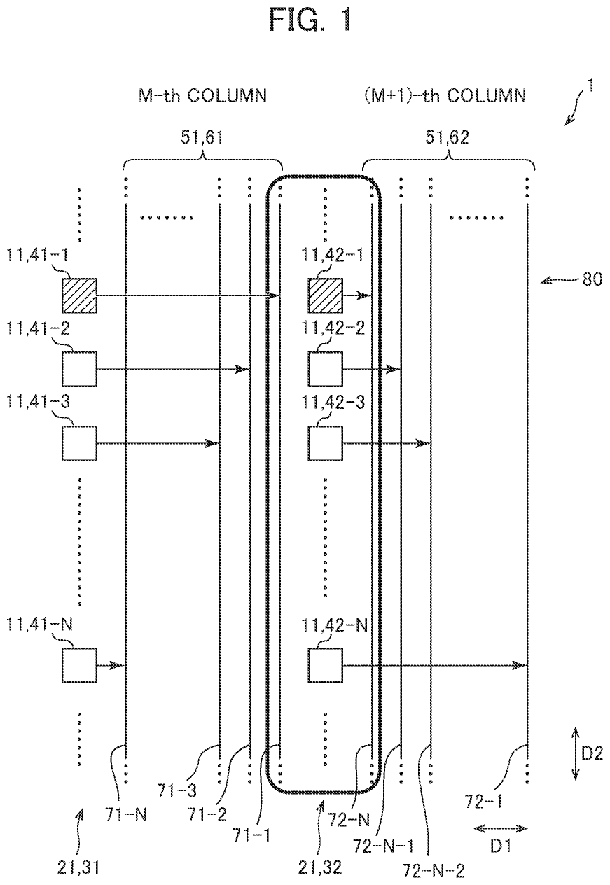

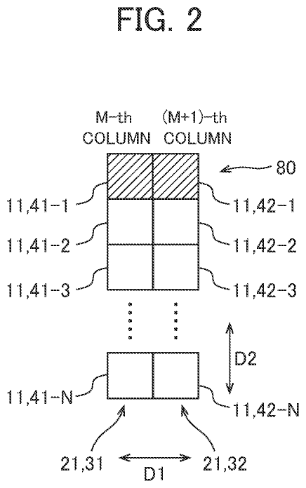

FIG. 1 is a schematic plan view of a solid-state imaging element in accordance with Embodiment 1. FIG. 2 is a schematic plan view of a layout of pixels in a first pixel column and a second pixel column in the solid-state imaging element in accordance with Embodiment 1.

A solid-state imaging element 1 in accordance with Embodiment 1 shown in FIG. 1 captures an image of a subject for output of image signals that is in accordance with the captured image. The solid-state imaging element 1 is, for example, a complementary metal oxide semiconductor (CMOS) image sensor.

Referring to FIGS. 1 and 2, the solid-state imaging element 1 includes a plurality of pixels 11.

The plurality of pixels 11 are disposed on a light-receiving face where an image of the subject is formed. Each pixel 11 in the plurality of pixels 11 receives light that will form a captured image of the subject, generates electric charge in accordance with incoming light by performing photoelectric conversion on the incoming light, and produces pixel signals in accordance with the generated electric charge. Hence, the plurality of pixels 11 respectively produce a plurality of pixel signals that constitute image signals to be outputted.

The plurality of pixels 11 are arranged in row direction D1 and column direction D2 like a matrix. Therefore, referring to FIGS. 1 and 2, the plurality of pixels 11 include a plurality of pixel columns 21. Each pixel column 21 in the plurality of pixel columns 21 extends in column direction D2. The plurality of pixel columns 21 are arranged parallel to each other in row direction D1. The plurality of pixel columns 21 include a first pixel column 31 and a second pixel column 32. The first pixel column 31 is located in an M-th column. The second pixel column 32 is located in an (M+1)-th column and adjacent to the first pixel column 31.

Each pixel column 21 includes a plurality of pixels 11. The plurality of pixels 11 in each pixel column 21 are arranged in column direction D2. Therefore, referring to FIGS. 1 and 2, the first pixel column 31 includes a plurality of first pixels 41-1, 41-2, 41-3, . . . , and 41-N. The first pixels 41-1, 41-2, 41-3, . . . , and 41-N are arranged in column direction D2. The second pixel column 32 includes a plurality of second pixels 42-1, 42-2, 42-3, . . . , and 42-N. The second pixels 42-1, 42-2, 42-3, . . . , and 42-N are arranged in column direction D2.

Referring to FIGS. 1 and 2, the solid-state imaging element 1 includes a plurality of pixel output line groups 51.

The plurality of pixel output line groups 51 are arranged parallel to each other in row direction D1. The plurality of pixel output line groups 51 are respectively disposed along the plurality of pixel columns 21. The plurality of pixel output line groups 51 are connected respectively to the plurality of pixel columns 21. The plurality of pixel output line groups 51 respectively read out pixel signals produced by the plurality of pixel columns 21. The plurality of pixel output line groups 51 include a first pixel output line group 61 and a second pixel output line group 62. The first pixel output line group 61 is located in the M-th column. The second pixel output line group 62 is located in the (M+1)-th column and adjacent to the first pixel output line group 61.

Referring to FIGS. 1 and 2, the first pixel output line group 61 includes a plurality of first pixel output lines 71-1, 71-2, 71-3, . . . , and 71-N. The first pixel output lines 71-1, 71-2, 71-3, . . . , and 71-N all extend in column direction D2. The first pixel output lines 71-1, 71-2, 71-3, . . . , and 71-N are arranged parallel to each other in row direction D1. The first pixel output lines 71-1, 71-2, 71-3, . . . , and 71-N are connected respectively to the first pixels 41-1, 41-2, 41-3, . . . , and 41-N. Therefore, the pixel signals produced by the first pixels 41-1, 41-2, 41-3, . . . , and 41-N are transferred respectively to the first pixel output lines 71-1, 71-2, 71-3, . . . , and 71-N. The first pixel output lines 71-1, 71-2, 71-3, . . . , and 71-N respectively read out the pixel signals produced by, and transferred from, the first pixels 41-1, 41-2, 41-3, . . . , and 41-N.

The second pixel output line group 62 includes a plurality of second pixel output lines 72-1, . . . , 72-N-2, 72-N-1, and 72-N. The second pixel output lines 72-1, . . . , 72-N-2, 72-N-1, and 72-N all extend in column direction D2. The second pixel output lines 72-1, . . . , 72-N-2, 72-N-1, and 72-N are arranged parallel to each other in row direction D1. The second pixel output lines 72-1, . . . , 72-N-2, 72-N-1, and 72-N are connected respectively to the second pixels 42-N, . . . , 42-3, 42-2, and 42-1. Therefore, the pixel signals produced by the second pixels 42-N, . . . , 42-3, 42-2, and 42-1 are transferred respectively to the second pixel output lines 72-1, . . . , 72-N-2, 72-N-1, and 72-N. In addition, the second pixel output lines 72-1, . . . , 72-N-2, 72-N-1, and 72-N respectively read out the pixel signals produced by, and transferred from, the second pixels 42-N, . . . , 42-3, 42-2, and 42-1.

The first pixel output lines 71-1, 71-2, 71-3, . . . , and 71-N and the second pixel output lines 72-1, . . . , 72-N-2, 72-N-1, and 72-N simultaneously read out the pixel signals produced by the first pixels 41-1, 41-2, 41-3, . . . , and 41-N and the second pixels 42-N, . . . , 42-3, 42-2, and 42-1.

### 1.2 Pixels Connected to Closest Pixel Output Lines

The first pixel output lines 71-1, 71-2, 71-3, . . . , and 71-N include the first closest pixel output line 71-1 which is located closest to the second pixel output lines 72-1, . . . , 72-N-2, 72-N-1, and 72-N. The first closest pixel output line 71-1 is located on one of the sides of the flux of the first pixel output lines 71-1, 71-2, 71-3, . . . , and 71-N with respect to row direction D1. The second pixel output lines 72-1, . . . , 72-N-2, 72-N-1, and 72-N include the second closest pixel output line 72-N which is located closest to the first pixel output lines 71-1, 71-2, 71-3, . . . , and 71-N. The second closest pixel output line 72-N is located on another one of the sides of the flux of the second pixel output lines 72-1, . . . , 72-N-2, 72-N-1, and 72-N with respect to row direction D1.

The first closest pixel output line 71-1 is connected to the first pixel 41-1 which is one of the plurality of first pixels 41-1, 41-2, 41-3, . . . , and 41-N. The second closest pixel output line 72-N is connected to the second pixel 42-1 which is one of the plurality of second pixel 42-1, 42-2, 42-3, . . . , and 42-N. The first pixel 41-1 and the second pixel 42-1 are disposed in a common pixel row 80. Therefore, the first pixel 41-1 and the second pixel 42-1 are located close to each other. Hence, the first closest pixel output line 71-1 and the second closest pixel output line 72-N simultaneously read out the pixel signals produced by the first pixel 41-1 and the second pixel 42-1 which are located close to each other respectively. This structure enables restraining reduced image quality that could be caused by crosstalk between the first closest pixel output line 71-1 and the second closest pixel output line 72-N.

### 1.3 Comparison of Reference Example 1 and Embodiment 1

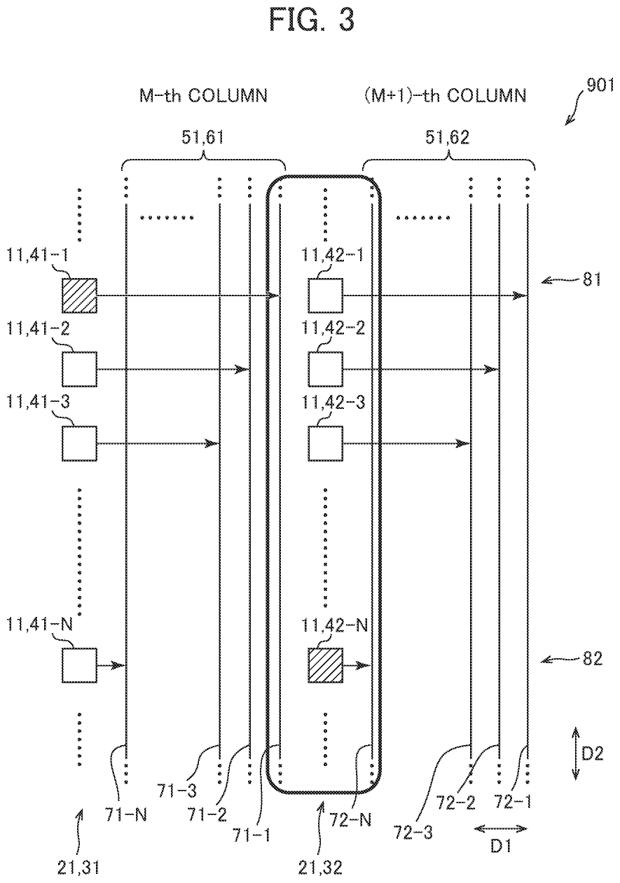

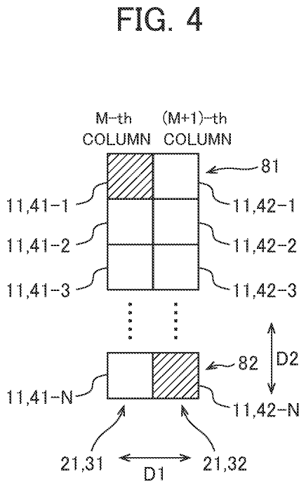

FIG. 3 is a schematic plan view of a solid-state imaging element in accordance with Reference Example 1. FIG. 4 is a schematic plan view of a layout of pixels in a first pixel column and a second pixel column in the solid-state imaging element in accordance with Reference Example 1.

Referring to FIGS. 3 and 4, a solid-state imaging element 901 in accordance with Reference Example 1 differs from the solid-state imaging element 1 in accordance with Embodiment 1 in that the first pixel 41-1 and the second pixel 42-N, which are connected respectively to the first closest pixel output line 71-1 and the second closest pixel output line 72-N, are respectively included in mutually different, first and second pixel rows 81 and 82.

Therefore, in the solid-state imaging element 901 in accordance with Reference Example 1, the first pixel 41-1 and the second pixel 42-1, which are connected respectively to the first closest pixel output line 71-1 and the second closest pixel output line 72-N, are located far from each other. Hence, the first closest pixel output line 71-1 and the second closest pixel output line 72-N simultaneously read out the pixel signals produced by the first pixel 41-1 and the second pixel 42-1 which are located far from each other respectively. This structure can lead to reduced image quality that could be caused by crosstalk between the first closest pixel output line 71-1 and the second closest pixel output line 72-N.

In contrast, in the solid-state imaging element 1 in accordance with Embodiment 1, the first pixel 41-1 and the second pixel 42-1, which are connected respectively to the first closest pixel output line 71-1 and the second closest pixel output line 72-N, are located close to each other. Hence, the first closest pixel output line 71-1 and the second closest pixel output line 72-N simultaneously read out the pixel signals produced by the first pixel 41-1 and the second pixel 42-1 respectively. This structure enables restraining reduced image quality that could be caused by crosstalk between the first closest pixel output line 71-1 and the second closest pixel output line 72-N.

### 1.4 Pixels Connected to Plurality of First Pixel Output Lines

Referring to FIGS. 1 and 2, the first pixels 41-1, 41-2, 41-3, . . . , and 41-N are arranged in column direction D2 in the stated order. In addition, the first pixel output lines 71-1, 71-2, 71-3, . . . , and 71-N are arranged in row direction D1 in the stated order. Therefore, when the first pixel output lines 71-1, 71-2, 71-3, . . . , and 71-N are connected respectively to the first pixels 41-1, 41-2, 41-3, . . . , and 41-N, two adjacent pixel output lines among the first pixel output lines 71-1, 71-2, 71-3, . . . , and 71-N are connected respectively to two mutually closest pixels among the first pixels 41-1, 41-2, 41-3, . . . , and 41-N. For example, the two adjacent pixel output lines 71-1 and 71-2 are connected respectively to the two mutually closest pixels 41-1 and 41-2. Hence, the two pixels connected respectively to the two adjacent pixel output lines are located closest to each other. Hence, the two adjacent pixel output lines simultaneously read out the pixel signals produced by the two mutually closest pixels respectively. This structure enables restraining reduced image quality that could be caused by crosstalk between the two adjacent pixel output lines. The same description applies to the plurality of pixels included in the pixel columns other than the first pixel column 31 and the plurality of pixel output lines included in the pixel output lines other than the first pixel output line group 61.

1.5 Wiring Layer Containing Pixel Output Lines and Wiring Lines Other than Pixel Output Lines

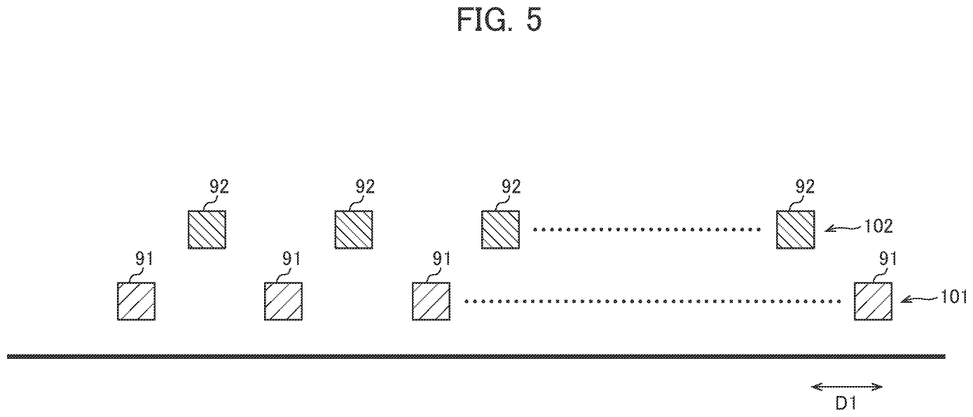

FIG. 5 is a schematic cross-sectional view of a plurality of pixel output lines and a plurality of wiring lines other than the plurality of pixel output lines in the solid-state imaging element in accordance with Embodiment 1.

Referring to FIG. 5, the solid-state imaging element 1 includes a plurality of pixel output lines 91 and a plurality of wiring lines 92 other than the plurality of pixel output lines 91.

The plurality of pixel output lines 91 are connected respectively to the plurality of pixels 11. Therefore, the pixel signals produced by the plurality of pixels 11 are transferred respectively to the plurality of pixel output lines 91. In addition, the plurality of pixel output lines 91 respectively read the pixel signals produced by, and transferred from, the plurality of pixels 11.

The plurality of pixel output lines 91 include a plurality of pixel output lines included in each one of the plurality of pixel output line groups 51. Therefore, the plurality of pixel output lines 91 include the plurality of first pixel output lines 71-1, 71-2, 71-3, . . . , and 71-N in the first pixel output line group 61 and the plurality of second pixel output lines 72-1, . . . , 72-N-2, 72-N-1, and 72-N in the second pixel output line group 62.

The plurality of pixel output lines 91 are disposed in a common wiring layer 101. This structure enables restraining variations in the properties of the plurality of pixel output lines 91, which in turn enables restraining reduced image quality that could be caused by crosstalk between the two adjacent pixel output lines 91.

The plurality of wiring lines 92 are disposed in a wiring layer 102 that is a different layer from the common wiring layer 101. Hence, the plurality of wiring lines 92 are not disposed in the common wiring layer 101 where the plurality of pixel output lines 91 are disposed, and it is only the plurality of pixel output lines 91 that are disposed in the common wiring layer 101.

The plurality of pixel output lines 91 can be disposed alone in the common wiring layer 101, in other words, no shield lines need to be disposed in the common wiring layer 101, because reduced image quality that could be caused by crosstalk between the first closest pixel output line 71-1 and the second closest pixel output line 72-N is restrained by disposing, close to each other, the first pixel 41-1 and the second pixel 42-1 which are connected respectively to the first closest pixel output line 71-1 and the second closest pixel output line 72-N.

In addition, by disposing the plurality of pixel output lines 91 alone in the common wiring layer 101, increases in the wiring density of the wiring lines disposed in the common wiring layer 101 can be restrained that could be caused by the provision of the plurality of wiring lines 92 in the common wiring layer 101. The structure hence enables increasing the number of the plurality of pixel output lines 91 that can be disposed in the common wiring layer 101 under a wiring density condition where the number of wiring lines that can be disposed in the common wiring layer 101 is restricted by layout rules.

### 1.6 Comparison of Reference Example 2 and Embodiment 1

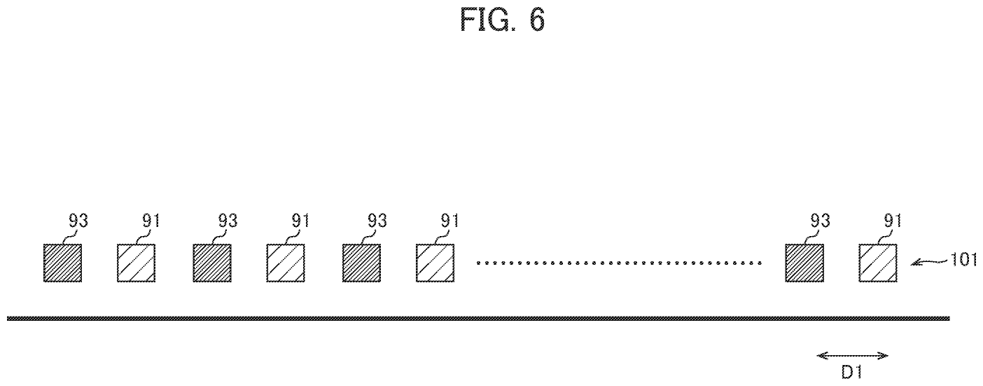

FIG. 6 is a schematic cross-sectional view of a plurality of pixel output lines and a plurality of shield lines in a solid-state imaging element in accordance with Reference Example 2.

Referring to FIG. 6, the solid-state imaging element in accordance with Reference Example 2 differs from the solid-state imaging element 1 in accordance with Embodiment 1 in that the plurality of pixel output lines 91 and a plurality of shield lines 93 are disposed in the common wiring layer 101.

In the solid-state imaging element in accordance with Reference Example 2, one of the shield lines 93 is disposed between every two adjacent pixel output lines 91. Therefore, the pixel output lines 91 among the plurality of pixel output lines 91 are adjacent respectively to the shield lines 93. The plurality of shield lines 93 restrain crosstalk between the two adjacent pixel output lines 91 from becoming non-uniform due to differences between the pixel signals read out by the plurality of pixel output lines 91.

However, when the shield lines 93 are disposed between the two adjacent pixel output lines 91, the number of the plurality of pixel output lines 91 that can be disposed in the common wiring layer 101 decreases under a wiring density condition where the number of wiring lines that can be disposed in the common wiring layer 101 is restricted by layout rules.

In addition, when the pixel output lines 91 are adjacent respectively to the shield lines 93, electrical potential difference grows between the electrical potential of each pixel output line 91 and the electrical potential of an adjacent wiring line. Therefore, the pixel output line 91 reads out a pixel signal with a greater RC delay. Therefore, the solid-state imaging element in accordance with Reference Example 2 is not suited to high speed pixel signal readout.

In contrast, the solid-state imaging element 1 in accordance with Embodiment 1 allows for increases in the number of the plurality of pixel output lines 91 that can be disposed in the common wiring layer 101 under a wiring density condition where the number of wiring lines that can be disposed in the common wiring layer 101 is restricted by layout rules.

In addition, in the solid-state imaging element 1 in accordance with Embodiment 1, each pixel output line 91 is adjacent to another pixel output line 91. When each pixel output line 91 is adjacent to another pixel output line 91, electrical potential difference decreases between the electrical potential of each pixel output line 91 and the electrical potential of an adjacent wiring line. Therefore, the pixel output line 91 reads out a pixel signal with a smaller RC delay. Therefore, the solid-state imaging element 1 in accordance with Embodiment 1 is suited to high speed pixel signal readout.

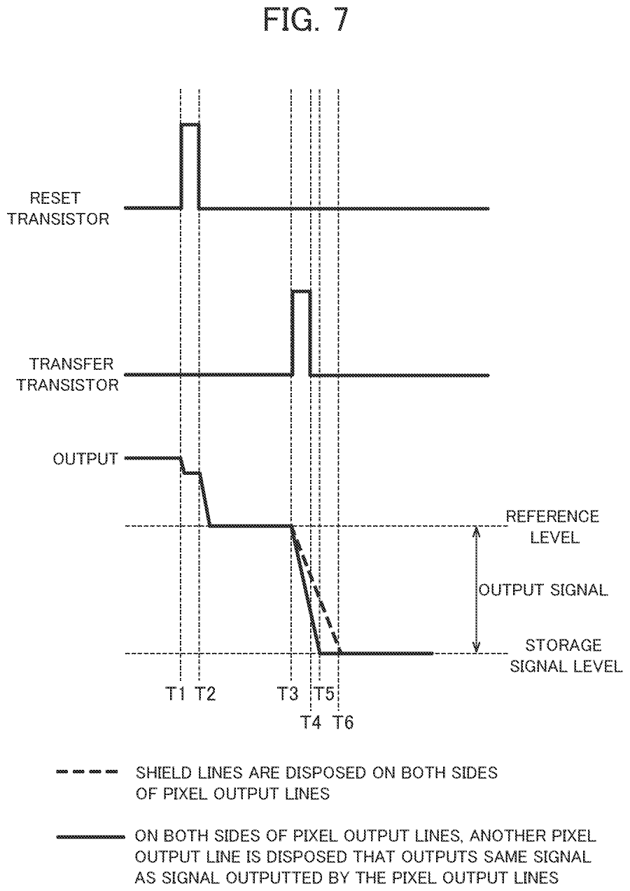

FIG. 7 is a timing chart illustrating temporal changes in the ON/OFF state of a reset transistor, the ON/OFF state of a transfer transistor, and the voltage output from a pixel output line when there is provided a shield line on each side of a pixel output line and when on each side of a pixel output line, there is provided another pixel output line that outputs the same signal as does the pixel output line.

Referring to FIG. 7, both when there is provided a shield line on each side of a pixel output line and when there is provided another pixel output line on each side of a pixel output line, the reset transistor is turned on from timing T1 to timing T2. The voltage output from the pixel output line is reduced to the reference level in response to the reset transistor being turned on.

In addition, the transfer transistor is turned on from timing T3 to timing T4 after the voltage output from the pixel output line is changed to the reference level. The voltage output from the pixel output line is reduced to a storage signal level in response to the transfer transistor being turned on.

The difference between the reference level and the storage signal level provides the output signal.

A problem to high speed pixel signal readout is the behavior of the voltage output from the pixel output line when the reset transistor is turned on, rather than the behavior of the voltage output from the pixel output line when the transfer transistor is turned on, and is in particular the settling time from timing T3 when the transfer transistor is changed from OFF to ON to when the voltage output from the pixel output line is reduced to the storage signal level.

When there is provided a shield line on each side of a pixel output line, the settling time has a duration equal to the period from timing T4 to timing T6 both shown in FIG. 7. On the other hand, when there is provided another pixel output line on each side of a pixel output line, the settling time has a duration equal to the period from timing T4 to timing T5 both shown in FIG. 7. It would be appreciated from FIG. 7 that the latter settling time is shorter than the former settling time. This indicates that the resultant solid-state imaging element is more suited to high speed pixel signal readout when there is provided another pixel output line on each side of a pixel output line than when there is provided a shield line on each side of a pixel output line.

1.7 Symmetry of Wiring Lines Other than Pixel Output Lines

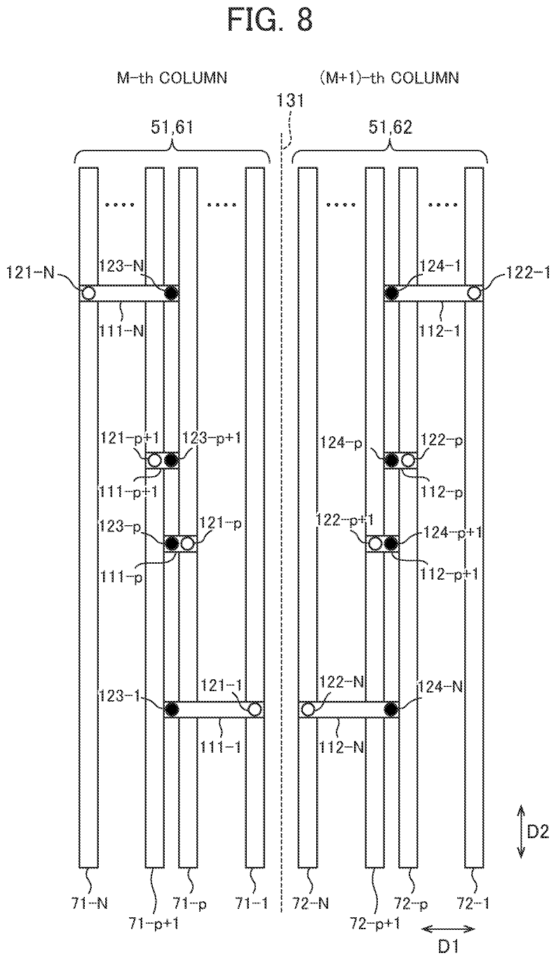

FIG. 8 is a schematic plan view of a plurality of first wiring lines, a plurality of second wiring lines, a plurality of first vias, a plurality of second vias, a plurality of third vias, and a plurality of fourth vias in the solid-state imaging element in accordance with Embodiment 1.

Referring to FIG. 8, the solid-state imaging element 1 includes a plurality of first wiring lines 111-1, . . . , 111-p, 111-p+1, . . . , and 111-N, a plurality of second wiring lines 112-1, . . . , 112-p, 112-p+1, . . . , and 112-N, a plurality of first vias 121-1, . . . , 121-p, 121-p+1, . . . , and 121-N, a plurality of second vias 122-1, . . . , 122-p, 122-p+1, . . . , and 122-N, a plurality of third vias 123-1, . . . , 123-p, 123-p+1, . . . , and 123-N, and a plurality of fourth vias 124-1, . . . , 124-p, 124-p+1, . . . , and 124-N.

The first wiring lines 111-1, . . . , 111-p, 111-p+1, . . . , and 111-N are connected to the first pixel output lines 71-1, . . . , 71-p, 71-p+1, . . . , and 71-N through the first vias 121-1, . . . , 121-p, 121-p+1, . . . , and 121-N respectively. The second wiring lines 112-1, . . . , 112-p, 112-p+1, . . . , and 112-N are connected to the second pixel output lines 72-1, . . . , 72-p, 72-p+1, . . . , and 72-N through the second vias 122-1, . . . , 122-p, 122-p+1, . . . , and 122-N respectively.

In addition, the first wiring lines 111-1, . . . , 111-p, 111-p+1, . . . , and 111-N are connected to other wiring lines through the third vias 123-1, . . . , 123-p, 123-p+1, . . . , and 123 -N respectively. The second wiring lines 112-1, . . . , 112-p, 112-p+1, . . . , and 112-N are connected to other wiring lines through the fourth vias 124-1, . . . , 124-p, 124-p+1, . . . , and 124-N respectively.

The first wiring lines 111-1, . . . , 111-p, 111-p+1, . . . , and 111-N and the second wiring lines 112-1, . . . , 112-p, 112-p+1, . . . , and 112-N are disposed in a wiring layer other than the common wiring layer 101 where the first pixel output lines 71-1, . . . , 71-p, 71-p+1, . . . , and 71-N and the second pixel output lines 72-1, . . . , 72-p, 72-p+1, . . . , and 72-N are disposed. The first wiring lines 111-1, . . . , 111-p, 111-p+1, . . . , and 111-N and the second wiring lines 112-N, . . . , 112-p+1, 112-p, . . . , and 112-1 are disposed symmetrically in a plan view with respect to an imaginary line 131 that passes through a middle point of the first wiring lines 111-1, . . . , 111-p, 111-p+1, . . . , and 111-N and the second wiring lines 112-N, . . . , 112-p+1, 112-p, . . . , and 112-1. This structure hence enables bringing the lengths of the second wiring lines 112-N, . . . , 112-p+1, 112-p, . . . , and 112-1 closer respectively to the lengths of the corresponding, first wiring lines 111-1, . . . , 111-p, 111-p+1, . . . , and 111-N. That in turn enables bringing the parasitic capacitances provided by the second wiring lines 112-N, . . . , 112-p+1, 112-p, . . . , and 112-1 closer to the parasitic capacitances provided by the first wiring lines 111-1, . . . , 111-p, 111-p+1, . . . , and 111-N, which enables restraining variations in the properties of the first wiring lines 111-1, . . . , 111-p, 111-p+1, . . . , and 111-N and variations in the properties of the second wiring lines 112-N, . . . , 112-p+1, 112-p, . . . , and 112-1.

### 1.8 Comparison of Reference Example 3 and Embodiment 1

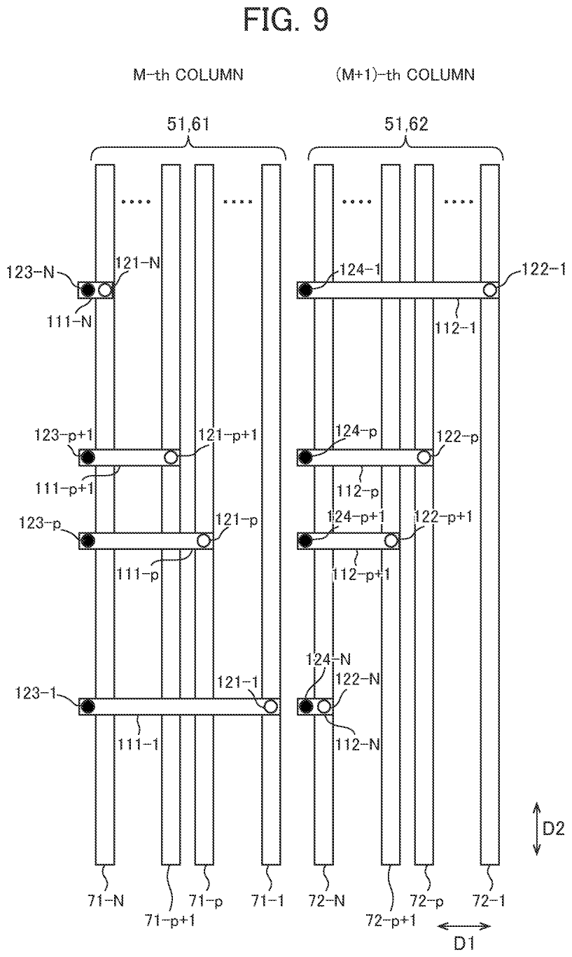

FIG. 9 is a schematic plan view of a plurality of first wiring lines, a plurality of second wiring lines, a plurality of first vias, a plurality of second vias, a plurality of third vias, and a plurality of fourth vias in a solid-state imaging element in accordance with Reference Example 3.

Referring to FIG. 9, the solid-state imaging element in accordance with Reference Example 3 differs from the solid-state imaging element 1 in accordance with Embodiment 1 in that the first wiring lines 111-1, . . . , 111-p, 111-p+1, . . . , and 111-N and the second wiring lines 112-N, . . . , 112-p+1, 112-p, . . . , and 112-1 are disposed asymmetrically in a plan view with respect to a line.

Since the first wiring lines 111-1, . . . , 111-p, 111-p+1, . . . , and 111-N and the second wiring lines 112-N, . . . , 112-p+1, 112-p, . . . , and 112-1 are disposed asymmetrically in a plan view with respect to a line in the solid-state imaging element in accordance with Reference Example 3, the lengths of the second wiring lines 112-N, . . . , 112-p+1, 112-p, . . . , and 112-1 respectively differ significantly from the lengths of the corresponding, first wiring lines 111-1, . . . , 111-p, 111-p+1, . . . , and 111-N. Therefore, the parasitic capacitances provided by the second wiring lines 112-N, . . . , 112-p+1, 112-p, . . . , and 112-1 differ significantly from the parasitic capacitances provided by the first wiring lines 111-1, . . . , 111-p, 111-p+1, . . . , and 111-N. The structure hence increases variations in the properties of the first wiring lines 111-1, . . . , 111-p, 111-p+1, . . . , and 111-N and variations in the properties of the second wiring lines 112-N, . . . , 112-p+1, 112-p, . . . , and 112-1.

In contrast, since the first wiring lines 111-1, . . . , 111-p, 111-p+1, . . . , and 111-N and the second wiring lines 112-N, . . . , 112-p+1, 112-p, . . . , and 112-1 are disposed symmetrically in a plan view with respect to a line in the solid-state imaging element 1 in accordance with Embodiment 1, the lengths of the second wiring lines 112-N, . . . , 112-p+1, 112-p, . . . , and 112-1 respectively do not differ significantly from the lengths of the corresponding, first wiring lines 111-1, . . . , 111-p, 111-p+1, . . . , and 111-N. Therefore, the parasitic capacitances provided by the second wiring lines 112-N, . . . , 112-p+1, 112-p, . . . , and 112-1 do not differ significantly from the parasitic capacitances provided by the first wiring lines 111-1, . . . , 111-p, 111-p+1, . . . , and 111-N. The structure hence reduces variations in the properties of the first wiring lines 111-1, . . . , 111-p, 111-p+1, . . . , and 111-N and variations in the properties of the second wiring lines 112-N, . . . , 112-p+1, 112-p, . . . , and 112-1.

### 1.9 Adjacent-Pixel-Output-Line Interval

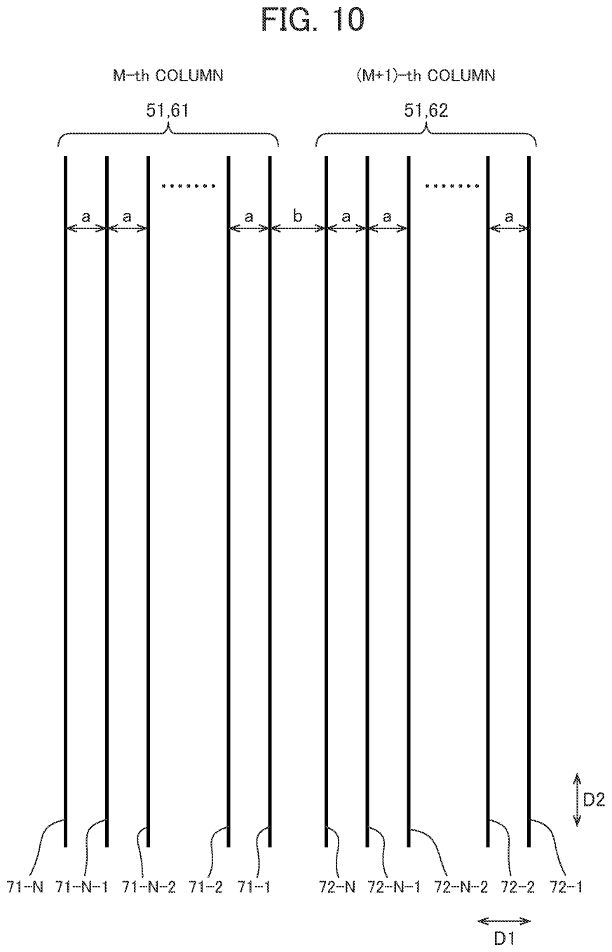

FIG. 10 is a schematic plan view of a plurality of first pixel output lines and a plurality of second pixel output lines in the solid-state imaging element in accordance with Embodiment 1.

Referring to FIG. 10, the plurality of first pixel output lines 71-1, 71-2, . . . , 71-N-2, 71-N-1, and 71-N have a fixed adjacent-pixel-output-line interval a. The structure hence enables restraining variations in the parasitic capacitances formed by the first pixel output lines 71-1, 71-2, . . . , 71-N-2, 71-N-1, and 71-N. That in turn enables restraining variations in the properties of the first pixel output lines 71-1, 71-2, . . . , 71-N-2, 71-N-1, and 71-N, which enables restraining reduced image quality that could be caused by crosstalk between the two adjacent pixel output lines included in the first pixel output lines 71-1, 71-2, . . . , 71-N-2, 71-N-1, and 71-N. The same description applies to the plurality of pixel output lines included in the pixel output line groups other than the first pixel output line group 61.

The first closest pixel output line 71-1 and the second closest pixel output line 72-N may have an adjacent-pixel-output-line interval b that differs from the adjacent-pixel-output-line interval a, but preferably has an adjacent-pixel-output-line interval b that is equal to the adjacent-pixel-output-line interval a. Variations can be restrained in the parasitic capacitances provided by the plurality of pixel output lines 91. The structure hence enables restraining variations in the properties of the plurality of pixel output lines 91, which enables restraining reduced image quality that could be caused by crosstalk between the two adjacent pixel output lines 91 included in the plurality of pixel output lines 91.

### 1.10 Front-Side Illumination Type and Backside Illumination Type

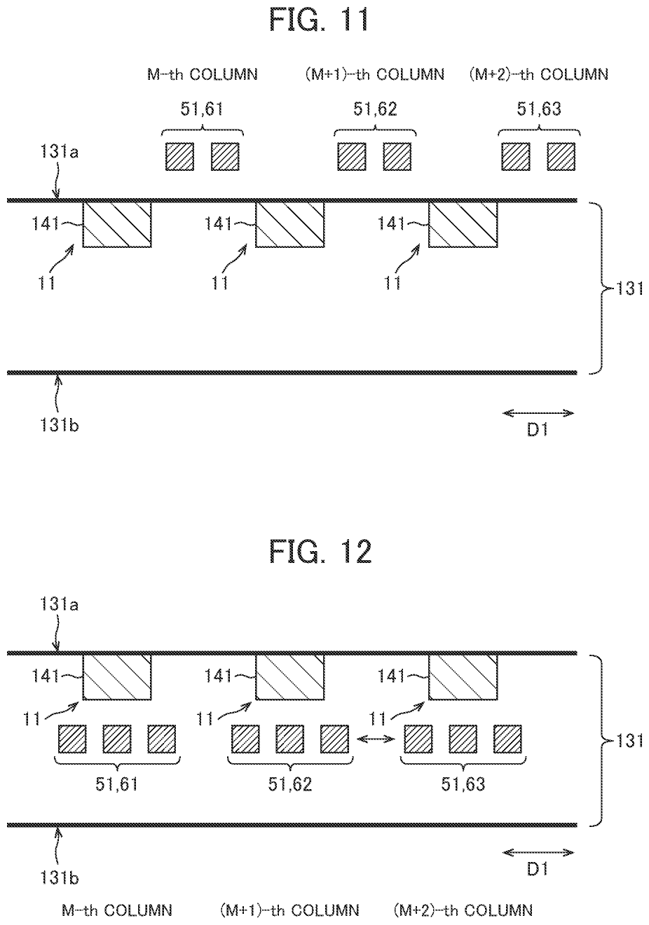

FIG. 11 is a schematic cross-sectional view of a semiconductor substrate, a plurality of first pixel output lines, a plurality of second pixel output lines, and a plurality of third pixel output lines in the solid-state imaging element in accordance with Embodiment 1 when the solid-state imaging element in accordance with Embodiment 1 is of a front-side illumination type. FIG. 12 is a schematic cross-sectional view of a semiconductor substrate, a plurality of first pixel output lines, a plurality of second pixel output lines, and a plurality of third pixel output lines in the solid-state imaging element in accordance with Embodiment 1 when the solid-state imaging element in accordance with Embodiment 1 is of a backside illumination type.

Referring to FIGS. 11 and 12, the solid-state imaging element 1 includes a semiconductor substrate 131, the first pixel output line group 61, the second pixel output line group 62, and a third pixel output line group 63 regardless of whether the solid-state imaging element 1 is of a front-side illumination type or of a backside illumination type.

The semiconductor substrate 131 has a first main face 131a and a second main face 131b. The first main face 131a and the second main face 131b are disposed opposite each other. The semiconductor substrate 131 includes the plurality of pixels 11 on the first main face 131a. Each pixel 11 in the plurality of pixels 11 includes a photodiode 141 that performs photoelectric conversion. The third pixel output line group 63 is located in an (M+2)-th column and adjacent to the second pixel output line group 62.

Referring to FIG. 11, when the solid-state imaging element 1 is of a front-side illumination type, the first pixel output line group 61, the second pixel output line group 62, and the third pixel output line group 63 are disposed on the first main face 131a.

In contrast, referring to FIG. 12, when the solid-state imaging element 1 is of a backside illumination type, the first pixel output line group 61, the second pixel output line group 62, and the third pixel output line group 63 are disposed underneath the first main face 131a. Therefore, the plurality of first pixel output lines in the first pixel output line group 61, the plurality of second pixel output lines in the second pixel output line group 62, and the plurality of third pixel output lines in the third pixel output line group 63 are disposed closer to the second main face 131b than to the first main face 131a. Therefore, when the solid-state imaging element 1 is of a backside illumination type, the solid-state imaging element 1 includes a through-electrode that runs through the semiconductor substrate 131 in the thickness direction thereof. When the solid-state imaging element 1 is of a non-stack type, the through-electrode is used to pull up the electric signal on the second main face 131b side to the pad disposed on the first main face 131a side. In addition, when the solid-state imaging element 1 is of a stack type that includes a sensor chip and a logic chip, the through-electrode is used to electrically connect the sensor chip and the logic chip to each other.

The number of the plurality of pixel output lines included in a pixel output line group is likely to be greater when the solid-state imaging element 1 is of a backside illumination type than when the solid-state imaging element 1 is of a front-side illumination type. Therefore, the distance that separates two adjacent pixel output line groups is likely to be smaller when the solid-state imaging element 1 is of a backside illumination type than when the solid-state imaging element 1 is of a front-side illumination type. Therefore, the effect of restraining reduced image quality that could be caused by crosstalk between two adjacent pixel output lines is more evident when the solid-state imaging element 1 is of a backside illumination type than when the solid-state imaging element 1 is of a front-side illumination type.

### 1.11 Connection to Circuit

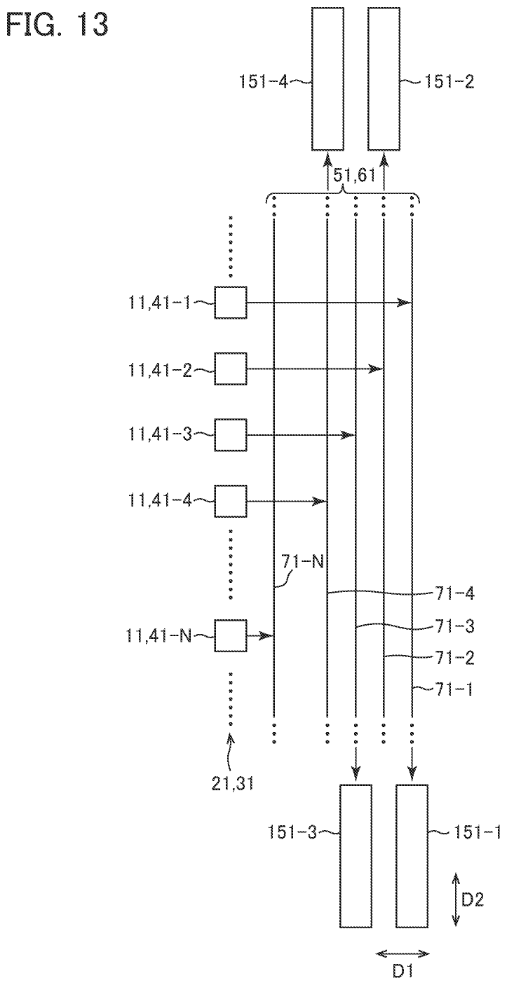

FIG. 13 is a schematic plan view of a plurality of first pixels, a plurality of first pixel output lines, a first circuit, and a second circuit in the solid-state imaging element in accordance with Embodiment 1.

Referring to FIG. 13, the solid-state imaging element 1 includes a plurality of first circuits 151-1, 151-3, . . . and a plurality of second circuits 151-2, 151-4, . . . .

The first circuits 151-1, 151-3, . . . are disposed on one of the sides of the first pixel output lines 71-1, 71-2, 71-3, 71-4, . . . , and 71-N with respect to column direction D2. The second circuits 151-2, 151-4, . . . are disposed on the other side of the first pixel output lines 71-1, 71-2, 71-3, 71-4, . . . , and 71-N with respect to column direction D2.

Some of the first pixel output lines 71-1, 71-2, 71-3, 71-4, . . . , and 71-N are connected to the first circuits 151-1, 151-3, . . . , and the rest is connected to the second circuits 151-2, 151-4, . . . . Therefore, the first pixel output lines 71-1, 71-2, 71-3, 71-4, . . . , and 71-N include: the pixel output lines 71-1, 71-3, . . . , which are connected respectively to the first circuits 151-1, 151-3, . . . , but not connected to the second circuits 151-2, 151-4, . . . ; and the pixel output lines 71-2, 71-4, . . . , which are connected to the second circuits 151-2, 151-4, . . . , but not connected to the first circuits 151-1, 151-3, . . . .

The distance between two adjacent circuits is allowed to be longer when the circuits 151-1, 151-2, 151-3, 151-4, . . . include: the first circuits 151-1, 151-3, . . . disposed on one of the sides of the first pixel output lines 71-1, 71-2, 71-3, . . . , and 71-N; and the second circuits 151-2, 151-4, . . . disposed on the other side of the first pixel output lines 71-1, 71-2, 71-3, . . . , and 71-N than when the plurality of circuits 151-1, 151-2, 151-3, 151-4, . . . include circuits disposed either only on one of the sides of the first pixel output lines 71-1, 71-2, 71-3, . . . , and 71-N or only on the other side of the first pixel output lines 71-1, 71-2, 71-3, . . . , and 71-N. This structure hence enables increasing the number of the first pixel output lines 71-1, 71-2, 71-3, . . . , and 71-N under a condition where the distance between the two adjacent circuits is restricted by layout rules.

The effect of restraining reduced image quality that could be caused by crosstalk between two adjacent pixel output lines becomes evident when the number of the plurality of pixel output lines in one pixel output line group 51 is increased. Therefore, in a solid-state imaging element 1, the effect of restraining reduced image quality that could be caused by crosstalk between adjacent pixel output lines becomes evident when the number of the first pixel output lines 71-1, 71-2, 71-3, . . . , and 71-N is increased. The same description applies to a plurality of pixel output lines included in the pixel output line groups 51 other than the first pixel output line group 61.

Each circuit in the plurality of circuits 151-1, 151-2, 151-3, 151-4, . . . processes pixel signals read out by a pixel output line connected to the circuit. The circuit is, for example, an analog/digital (A/D) conversion circuit or a correlated double sampling (CDS) circuit.

### 2 Embodiment 2

### 2.1 Solid-State Imaging Element

The following description will focus on differences between Embodiment 2 and Embodiment 1. The description may be silent about the structures and features of Embodiment 2 that are the same as those of Embodiment 1.

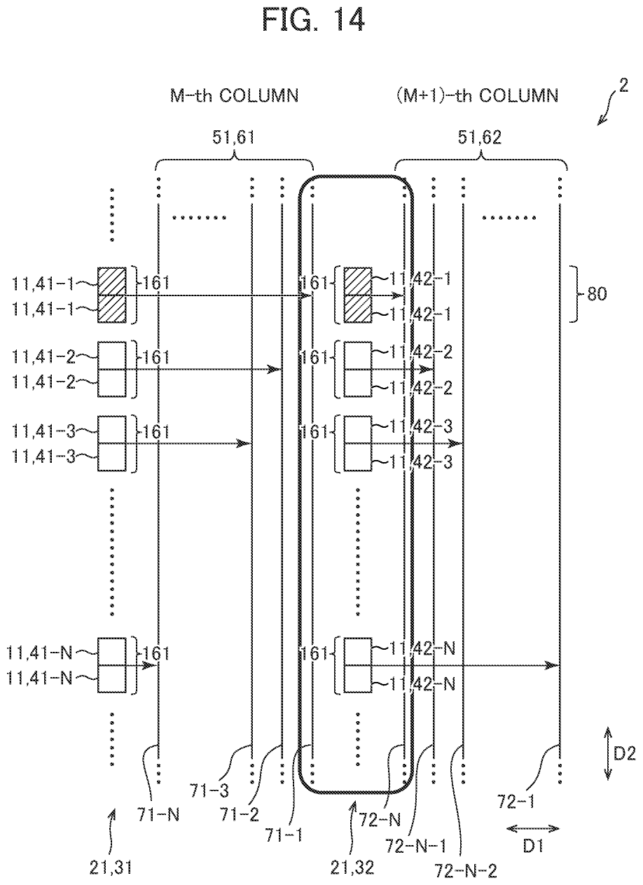

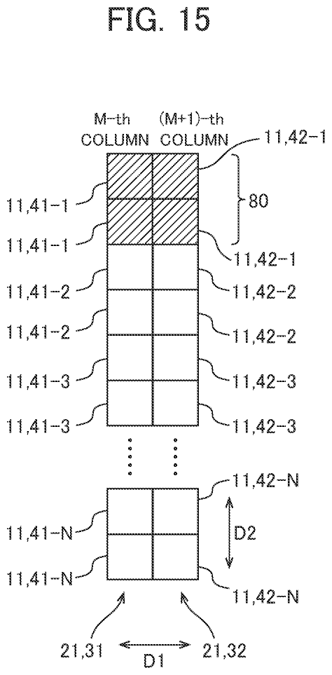

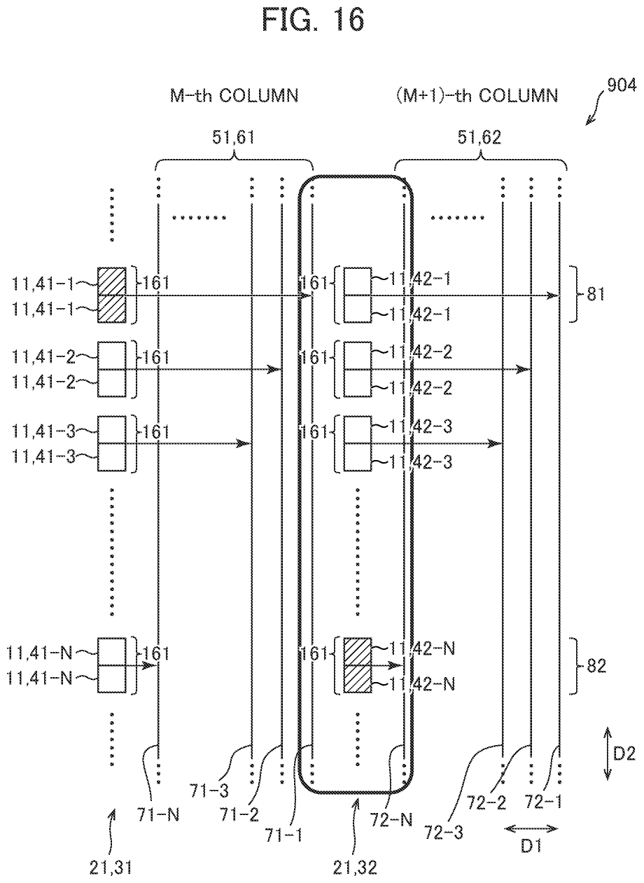

FIG. 14 is a schematic plan view of a solid-state imaging element in accordance with Embodiment 2. FIG. 15 is a schematic plan view of a layout of pixels in a first pixel column and a second pixel column in the solid-state imaging element in accordance with Embodiment 2.

Referring to FIGS. 14 and 15, in a solid-state imaging element 2 in accordance with Embodiment 2, the plurality of first pixels 41-1, 41-2, 41-3, . . . , and 41-N include floating diffusion (FD) common pixels 161. The FD common pixels 161 are two or more pixels that include a common FD to store generated electric charge in the common FD. A single pixel output line is connected to the two or more pixels included in the FD common pixels 161.

In the solid-state imaging element 2 in accordance with Embodiment 2, similarly to the solid-state imaging element 1 in accordance with Embodiment 1, the first pixel 41-1 and the second pixel 42-1, which are connected respectively to the first closest pixel output line 71-1 and the second closest pixel output line 72-N, are included in the same pixel row 80. Therefore, the first pixel 41-1 and the second pixel 42-1 are located close to each other. Hence, the first closest pixel output line 71-1 and the second closest pixel output line 72-N respectively read out the pixel signals produced by the first pixel 41-1 and the second pixel 42-1 located close to each other. This structure hence enables restraining reduced image quality that could be caused by crosstalk between the first closest pixel output line 71-1 and the second closest pixel output line 72-N.

### 2.2 Comparison Between Reference Example 4 and Embodiment 2

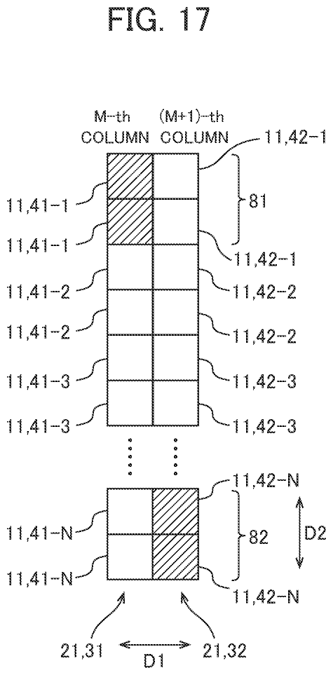

FIG. 16 is a schematic plan view of a solid-state imaging element in accordance with Reference Example 4. FIG. 17 is a schematic plan view of a layout of pixels in a first pixel column and a second pixel column in the solid-state imaging element in accordance with Reference Example 4.

Referring to FIGS. 16 and 17, a solid-state imaging element 904 in accordance with Reference Example 4 differs from the solid-state imaging element 2 in accordance with Embodiment 2 in that the first pixel 41-1 and the second pixel 42-N, which are connected respectively to the first closest pixel output line 71-1 and the second closest pixel output line 72-N, are included in different pixel rows, that is, in the first pixel row 81 and the second pixel row 82 respectively.

Therefore, in the solid-state imaging element 904 in accordance with Reference Example 4, the first pixel 41-1 and the second pixel 42-N, which are connected respectively to the first closest pixel output line 71-1 and the second closest pixel output line 72-N, are located far from each other. Hence, the first closest pixel output line 71-1 and the second closest pixel output line 72-N simultaneously read out the pixel signals produced by the first pixel 41-1 and the second pixel 42-N which are located far from each other respectively. This structure can lead to reduced image quality that could be caused by crosstalk between the first closest pixel output line 71-1 and the second closest pixel output line 72-N.

The first pixel 41-1 and the second pixel 42-N are located farther from each other in the solid-state imaging element 904 in accordance with Reference Example 4 than in the solid-state imaging element 901 in accordance with Reference Example 1. This is because a single pixel output line is connected to two or more pixels included in the FD common pixels 161. Therefore, when the first pixels 41-1, 41-2, 41-3, . . . , and 41-N include the FD common pixels 161, the first pixel 41-1 and the second pixel 42-N, which are connected respectively to the first closest pixel output line 71-1 and the second closest pixel output line 72-N, are even more required to be located close to each other.

In contrast, in the solid-state imaging element 2 in accordance with Embodiment 2, although the plurality of first pixels 41-1, 41-2, 41-3, . . . , and 41-N include the FD common pixels 161, the first pixel 41-1 and the second pixel 42-N, which are connected respectively to the first closest pixel output line 71-1 and the second closest pixel output line 72-N, are located close to each other. Hence, the first closest pixel output line 71-1 and the second closest pixel output line 72-N simultaneously read out the pixel signals produced by the first pixel 41-1 and the second pixel 42-N which are located close to each other respectively. This structure enables restraining reduced image quality that could be caused by crosstalk between the first closest pixel output line 71-1 and the second closest pixel output line 72-N.

### 3 Embodiment 3

The following description will focus on differences between Embodiment 3 and Embodiment 1. The description may be silent about the structures and features of Embodiment 3 that are the same as those of Embodiment 1.

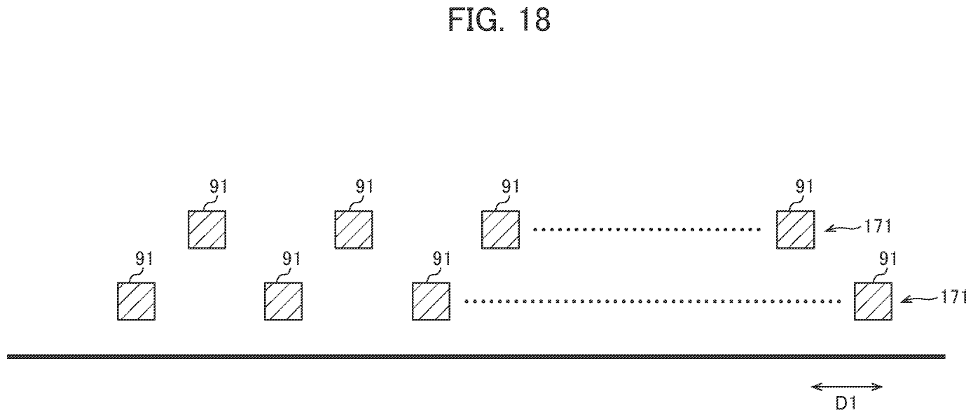

FIG. 18 is a schematic cross-sectional view of a plurality of pixel output lines in a solid-state imaging element in accordance with Embodiment 3.

Referring to FIG. 18, in the solid-state imaging element in accordance with Embodiment 3, the plurality of pixel output lines 91 are disposed in a distributed manner across a plurality of mutually different wiring layers 171. Therefore, the plurality of first pixel output lines 71-1, 71-2, 71-3, 71-4, and 71-N are also disposed in a distributed manner across the plurality of mutually different wiring layers 171. In addition, the plurality of second pixel output lines 72-1, 72-N-2, 72-N-1, and 72-N are also disposed in a distributed manner across the plurality of mutually different wiring layers 171. FIG. 17 shows a case where the plurality of wiring layers 171 are two wiring layers. However, the plurality of wiring layers 171 may be three or more wiring layers.

In the solid-state imaging element in accordance with Embodiment 3, the first pixel 41-1 and the second pixel 42-1, which are connected respectively to the first closest pixel output line 71-1 and the second closest pixel output line 72-N, are also located close to each other. Hence, the first closest pixel output line 71-1 and the second closest pixel output line 72-N simultaneously read out the pixel signals produced by the first pixel 41-1 and the second pixel 42-1 which are located close to each other respectively. This structure enables restraining reduced image quality that could be caused by crosstalk between the first closest pixel output line 71-1 and the second closest pixel output line 72-N.

The present disclosure is not limited to the description of the embodiments and examples above. Any structure detailed in the embodiments and examples may be replaced by a practically identical structure, a structure that delivers the same effect and function, or a structure that achieves the same purpose.

What is claimed is:

1. A solid-state imaging element comprising:
a plurality of pixels arranged in a matrix and including: a first pixel column including a plurality of first pixels; and a second pixel column including a plurality of second pixels, the second pixel column being located adjacent to the first pixel column;
a plurality of first pixel output lines connected respectively to the plurality of first pixels and arranged in a row direction; and
a plurality of second pixel output lines connected respectively to the plurality of second pixels and arranged in the row direction, wherein
the plurality of first pixel output lines include a first closest pixel output line located closest to the plurality of second pixel output lines,
the plurality of second pixel output lines include a second closest pixel output line located closest to the plurality of first pixel output lines,
the first closest pixel output line is connected to a first pixel included in the plurality of first pixels, and
the second closest pixel output line is connected to a second pixel included in the plurality of second pixels and disposed in a same pixel row as a pixel row that includes the first pixel.

2. The solid-state imaging element according to claim 1, wherein two adjacent pixel output lines included in the plurality of first pixel output lines are connected respectively to two mutually closest pixels included in the plurality of first pixels.

3. The solid-state imaging element according to claim 1, wherein the plurality of first pixel output lines are disposed in a single wiring layer.

4. The solid-state imaging element according to claim 3, further comprising:
a plurality of pixel output lines connected respectively to the plurality of pixels and disposed in the single wiring layer; and
wiring lines other than the plurality of pixel output lines, wherein
the wiring lines are disposed in a wiring layer other than the single wiring layer.

5. The solid-state imaging element according to claim 3, further comprising:
a plurality of first wiring lines connected respectively to the plurality of first pixel output lines; and
a plurality of second wiring lines connected respectively to the plurality of second pixel output lines, wherein
the plurality of first wiring lines and the plurality of second wiring lines are disposed in a wiring layer other than the single wiring layer and symmetrically in a plan view with respect to a line.

6. The solid-state imaging element according to claim 3, wherein the plurality of first pixel output lines have a fixed adjacent-pixel-output-line interval.

7. The solid-state imaging element according to claim 6, wherein the first closest pixel output line and the second closest pixel output line have an adjacent-pixel-output-line interval equal to the adjacent-pixel-output-line interval of the plurality of first pixel output lines.

8. The solid-state imaging element according to claim 3, further comprising a semiconductor substrate having a first main face and a second main face located opposite each other, the semiconductor substrate including the plurality of pixels on the first main face, wherein
the plurality of first pixel output lines and the plurality of second pixel output lines are disposed closer to the second main face than to the first main face, and
the solid-state imaging element is of a backside illumination type.

9. The solid-state imaging element according to claim 3, further comprising
a first circuit disposed on one of sides of the plurality of first pixel output lines with respect to a column direction; and
a second circuit disposed on another side of the plurality of first pixel output lines with respect to the column direction, wherein
the plurality of first pixel output lines include a pixel output line connected to the first circuit and a pixel output line connected to the second circuit.

10. The solid-state imaging element according to claim 3, wherein the plurality of first pixels include two or more pixels that include a common floating diffusion to store generated electric charge in the common floating diffusion.

11. The solid-state imaging element according to claim 1, wherein the plurality of first pixel output lines are disposed in a distributed manner across a plurality of mutually different wiring layers.
